(19) United States
(12) Patent Application Publication
(10) Pub. No.: US 2016/0351850 A1
(43) Pub. Date: Dec. 1, 2016

(54) ORGANIC LIGHT EMITTING DISPLAY DEVICE AND MANUFACTURING METHOD THEREOF

(71) Applicant: HON HAI PRECISION INDUSTRY CO., LTD., New Taipei (TW)

(72) Inventors: YI-HSIANG LIN, New Taipei (TW); CHANG-TING LIN, New Taipei (TW)

(21) Appl. No.: 14/843,595

(22) Filed: Sep. 2, 2015

(30) Foreign Application Priority Data
May 29, 2015 (TW) 104117547

(51) Int. Cl. H01L 51/52; H01L 51/56; H01L 27/32

(52) U.S. Cl. CPC H01L 51/5253; H01L 27/3211; H01L 27/322; H01L 51/56; H01L 2251/5369

(57) ABSTRACT

An organic light emitting display device includes a first substrate and a second substrate opposite to the first substrate. A pixel array is arranged between the first substrate and the second substrate to emit monochromatic light. A frit sealant is arranged between the first substrate and the second substrate to surround the pixel array. The organic light emitting display device further includes a color conversion layer doped with quantum dots and arranged on the second substrate.

### CROSS-REFERENCE TO RELATED APPLICATIONS

This application claims priority to Taiwanese Patent Application No. 104117547 filed on May 29, 2015, the contents of which are incorporated by reference herein.

### FIELD

The disclosure generally relates to an organic light emitting display device and a manufacturing method of the organic light emitting display device.

### BACKGROUND

An organic light emitting display device (OLED) includes an organic material layer serving as emitting device. During a process of manufacturing the OLED device, the emitting structure needs to be sealed to prevent damage from contaminates such as, oxygen and moisture. The organic light emitting display device is packaged with a glass substrate in a nitrogen environment and a desiccant is attached to the glass substrate. And then an epoxy is used as an encapsulation material to seal and prevent moisture and oxidation.

### BRIEF DESCRIPTION OF THE DRAWINGS

Implementations of the present technology will now be described, by way of example only, with reference to the attached figures, wherein:

FIG. 1 is a sectional view of an organic light emitting display device according to a first disclosure.

FIGS. 2-4 are sectional views illustrating a manufacturing method of the organic light emitting display device of FIG. 1.

FIG. 5 is a flowchart of the manufacturing method of the organic light emitting display device of FIG. 1.

FIG. 6 is a sectional view of an organic light emitting display device according to a second disclosure.

FIGS. 7-9 are sectional views illustrating a manufacturing method of the organic light emitting display device of FIG. 6.

FIG. 10 is a flowchart of the manufacturing method of the organic light emitting display device of FIG. 6.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

The term “comprising,” when utilized, means “including, but not necessarily limited to”; it specifically indicates open-ended inclusion or membership in the so-described combination, group, series and the like.

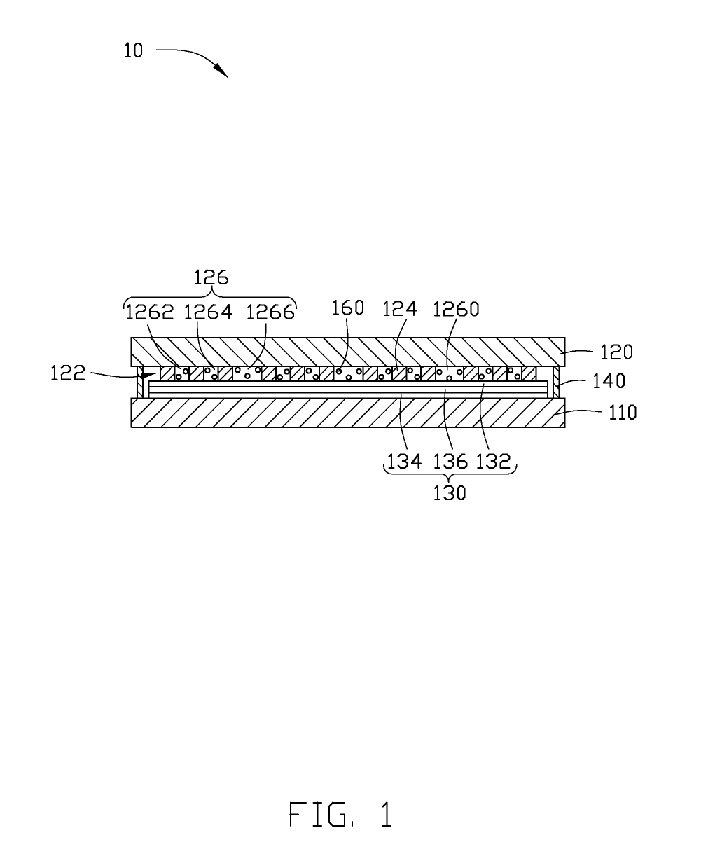

FIG. 1 illustrates an organic light emitting display device (OLED) 10 can include a first substrate 110 and a second substrate 120 opposite to the first substrate 110. A pixel array 130 is arranged between the first substrate 110 and the second substrate 120. The pixel array 130 can be an organic light emitting pixel array including a plurality of pixels. In the embodiment, the pixel array 130 is located on the first substrate 11. The organic light emitting display device 10 can further include a frit sealant 140 located between the first substrate 110 and the second substrate 120 to surround the pixel array 130. A color conversion layer 122 is arranged on the second substrate 120. Quantum dots 160 are doped in the color conversion layer 122.

The pixel array 130 can include a first electrode 132, a second electrode 134, and an organic light emitting medium 136 located between the first electrode 132 and the second electrode 134. When a voltage is generated between the first electrode 132 and the second electrode 134, the organic light emitting medium 136 emits monochromatic light. In the embodiment, the first substrate 110 can be a thin film transistor substrate to control a luminous intensity of the pixel array 130. The organic light emitting medium 136 emits a blue light. In other embodiments, the pixel array 130 can further include an electron emission layer, and an electron sending layer, a hole transport layer, and an hole inject layer.

The color conversion layer 122 receives the monochromatic light emitted from the organic light emitting medium 136 and converts the monochromatic light into light in different colors. The color conversion layer 122 can include a shielding wall 124 and a color conversion unit 126. The color conversion unit 126 can include a first color conversion unit 1262, a second color conversion unit 1264, and a third color conversion unit 1266, which corresponds to sub-pixels in each pixel. The shielding wall 124 is used to separate adjacent different color conversion units 1262-1264 from each other to avoid unexpected color mixing. The color conversion unit 126 is doped with a filler material 1260 and the quantum dots 160. In the embodiment, the filler material 1260 can be epoxy, acrylic plastic or other transparent material.

In the embodiment, the shielding wall 124 can be a black matrix. The first color conversion unit 1262 is doped with red quantum dots, the second color conversion unit 1264 is doped with green quantum dots, and the third color conversion unit 1266 is doped with blue quantum dots, which are corresponding to red, green and blue sub-pixels. In other embodiments, the third color conversion 1266 is not doped with quantum dots.

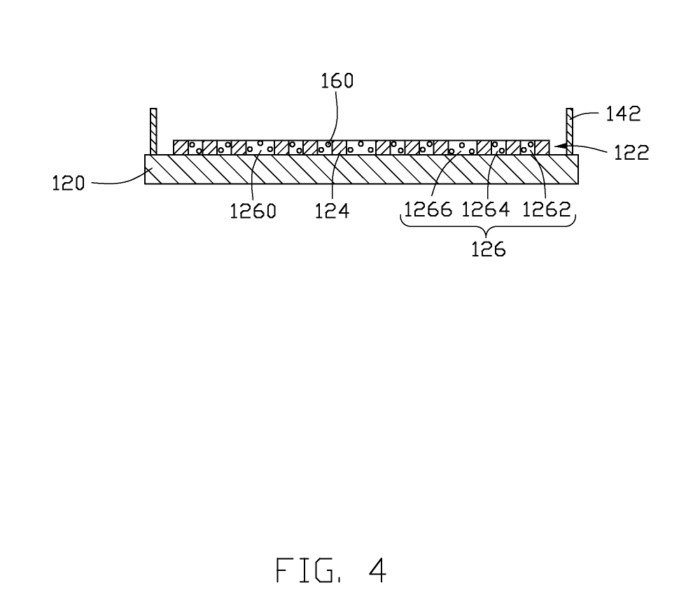

The frit sealant 140 is made of glass frit 142 (as shown in FIG. 4). The glass frit 142 is deposited on peripheral region of the second substrate 120 adjacent to edges of the second substrate 120 by pre-curing or pre-sintering. When the first substrate 110 is attached to the second substrate 120, the glass frit 142 is heated by laser to melt and form the frit sealant 140. The frit sealant 140 seals the first substrate 110 and the second substrate 120. In the embodiment, the glass frit 142 can include at least one kind of absorption ion. The absorption can be iron ion, copper ion, barium ion or neodymium ion. A height of the frit sealant 140 can be adjusted to control a space between the color conversion layer 122 and the pixel array 130. In the embodiment, there is no space between the color conversion layer 122 and the pixel array 130.

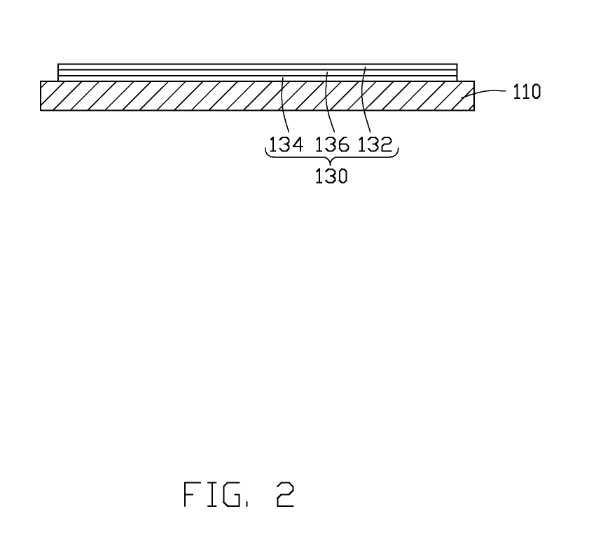

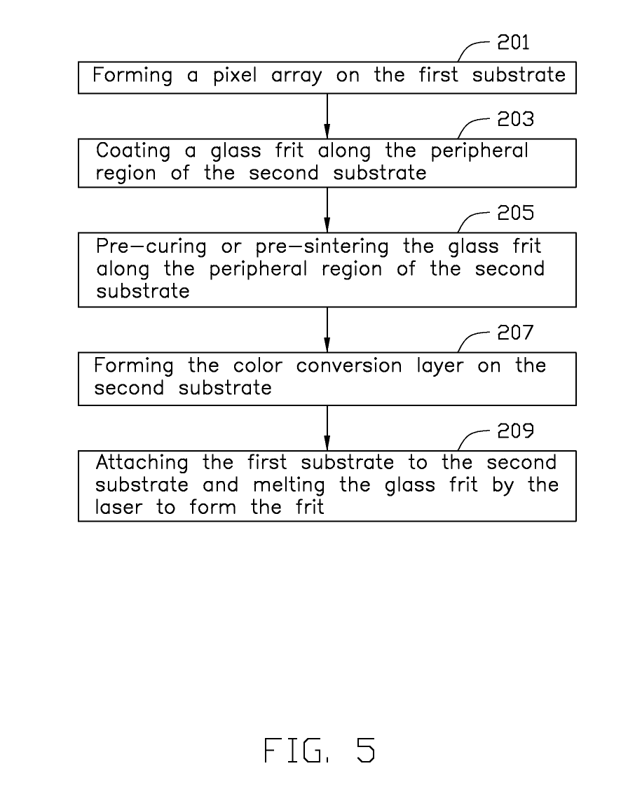

FIGS. 2-4 are sectional views illustrating a manufacturing method of the organic light emitting display device 10. FIG. 5 is a flowchart of the manufacturing method of the organic light emitting display device 10. The method is provided by way of example, as there are a variety of ways to carry out the method. Each block shown in FIG. 5 represents one or more processes, methods, or subroutines which are carried out in the example method. Furthermore, the order of blocks is illustrative only and the order of the blocks can change. Additional blocks can be added or fewer blocks may be utilized without departing from the scope of this disclosure. The example method can begin at block 201.

At block 201, FIG. 2 illustrates the pixel array 130 is formed on the first substrate 110. In the embodiment, the pixel array 130 emits monochromatic light.

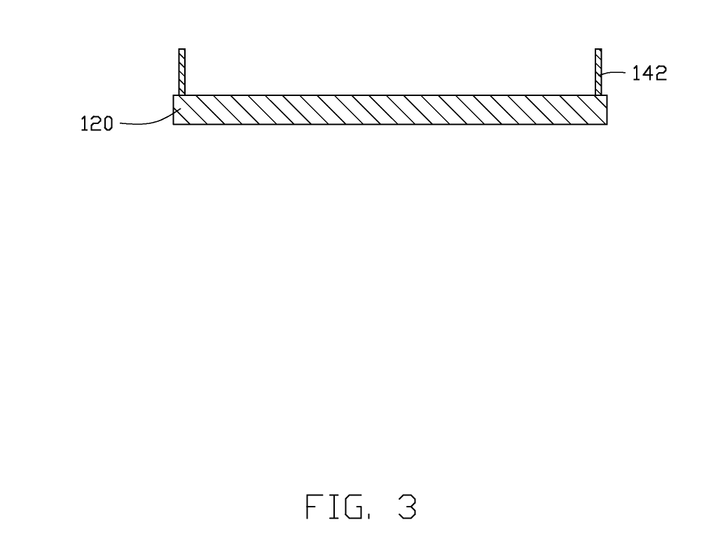

At block 203, FIG. 3 illustrates the color conversion layer 122 is formed on a second substrate 120. In detail, a shielding wall 124 is formed on the second substrate 120 at intervals. The filler material 1260 doped with quantum dots 160 is formed to fully fill into intervals of the shielding wall 124 by a micro-contact printing process, thereby forming the color conversion unit 126.

At block 205, FIG. 4 illustrates the glass frit 142 is deposited along the peripheral region of the second substrate 120. The glass frit 142 can be deposited on the second substrate 120 one millimeter away from the edges of the second substrate 120.

At block 207, FIG. 4 illustrates the glass frit 142 is pre-cured or pre-sintered along the edges of the second substrate 120 to surround the shielding wall 124.

At block 209, FIG. 1 illustrates the first substrate 110 is attached to the second substrate 120; the glass frit 142 is melted by the laser to form the frit sealant 140. In other embodiments, the glass frit 142 can be melted by infrared source.

In the embodiment, the organic light emitting display device 10 includes the frit sealant 140. The frit sealant 140 is made of inorganic material, thus the frit sealant 140 can block outside moisture or oxygen and the epoxy is omitted. Furthermore, when the organic light emitting display device is sealed by heat using a laser source, the second substrate with the color conversion layer serves as a packaging substrate and the color conversion layer also serves as a buffer material to ensure mechanical strength of the laser melting seal and make packaging more reliable.

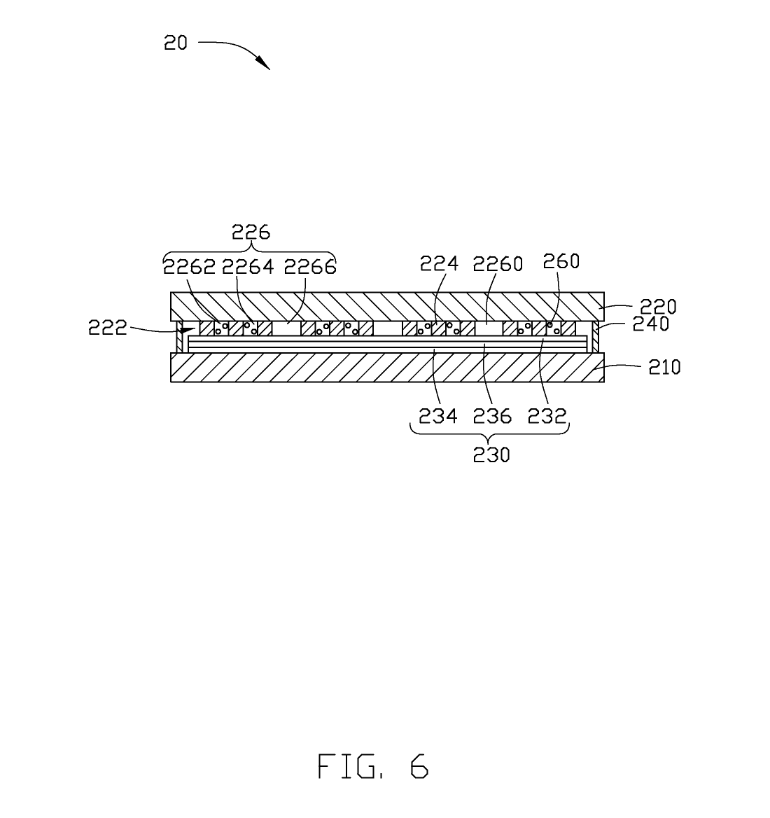

FIG. 6 illustrates an organic light emitting display device (OLED) 20 according to another embodiment of the invention. It includes a first substrate 210 and a second substrate 220 opposite to the first substrate 210. A pixel array 230 is arranged between the first substrate 210 and the second substrate 220. The pixel array 230 can be an organic light emitting pixel array including a plurality of pixels. In the embodiment, the pixel array 230 is located on the first substrate 21. The organic light emitting display device 20 can further include a frit sealant 240 located between the first substrate 210 and the second substrate 220. The pixel array 230 is surrounded by the first substrate 210, the second substrate and the frit sealant 240. A color conversion layer 222 is arranged on the second substrate 220. Quantum dots 260 are doped in the color conversion layer 222.

The pixel array 230 can include a first electrode 232, a second electrode 234, and an organic light emitting medium 236 located between the first electrode 232 and the second electrode 234. When a voltage is generated between to the first electrode 232 and the second electrode 234, the organic light emitting medium 236 emits monochromatic light. In the embodiment, the first substrate 210 can be a thin film transistor substrate to control a luminous intensity of the pixel array 230. The organic light emitting medium 236 emits a blue light. In other embodiments, the pixel array 230 can further include an electron emission layer, and an electron sending layer, a hole transport layer, and an hole injection layer.

The color conversion layer 222 receives the monochromatic light emitted from the organic light emitting medium 236 and converts the monochromatic light into light in different colors. The color conversion layer 240 can include a shielding wall 224 and a color conversion unit 226. The color conversion unit 222 can include a first color conversion unit 2262, a second color conversion unit 2264, and a third color conversion unit 2266, which corresponds to sub-pixels in each pixel. The shielding wall 224 is used to separate adjacent different color conversion units 2262-2264 from each other to avoid unexpected color mixing. The color conversion unit 226 is doped with a filler material 2260 and quantum dots 260. In the embodiment, the filler material 2260 can be epoxy, acrylic plastic or other transparent material.

In the embodiment, the shielding wall 224 can be a black matrix. The first color conversion unit 2262 is doped with red quantum dots, the second color conversion unit 2264 is doped with green quantum dots, and the third color conversion unit 2266 is doped with blue quantum dots, which are corresponding to red, green, and blue sub-pixels. In other embodiments, the third color conversion 2226 is not doped with quantum dots.

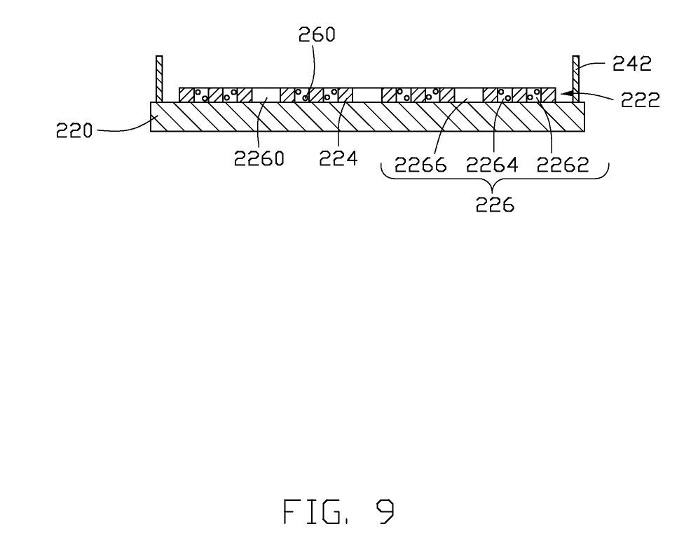

The frit sealant 240 is made of glass frit 242 (as shown in FIG. 9). The glass frit 242 is deposited on peripheral region of the second substrate 220 adjacent to edges of the second substrate 220 by pre curing or pre-sintering. When the first substrate 210 is attached to the second substrate 220, the glass frit 242 is heated by laser to melt the glass frit 242 and form the frit sealant 240. The frit sealant 240 seals the first substrate 210 and the second substrate 220. In the embodiment, the glass frit 242 can include at least one kind of absorption ion. The absorption can be iron ion, copper ion, barium ion or neodymium ion. A height of the frit sealant 240 can be adjusted to control a space between the color conversion layer 222 and the pixel array 230. In the embodiment, there is no space between the color conversion layer 222 and the pixel array 230.

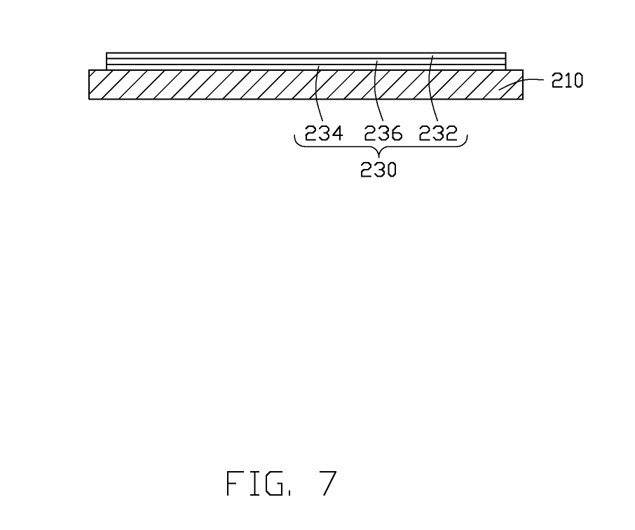

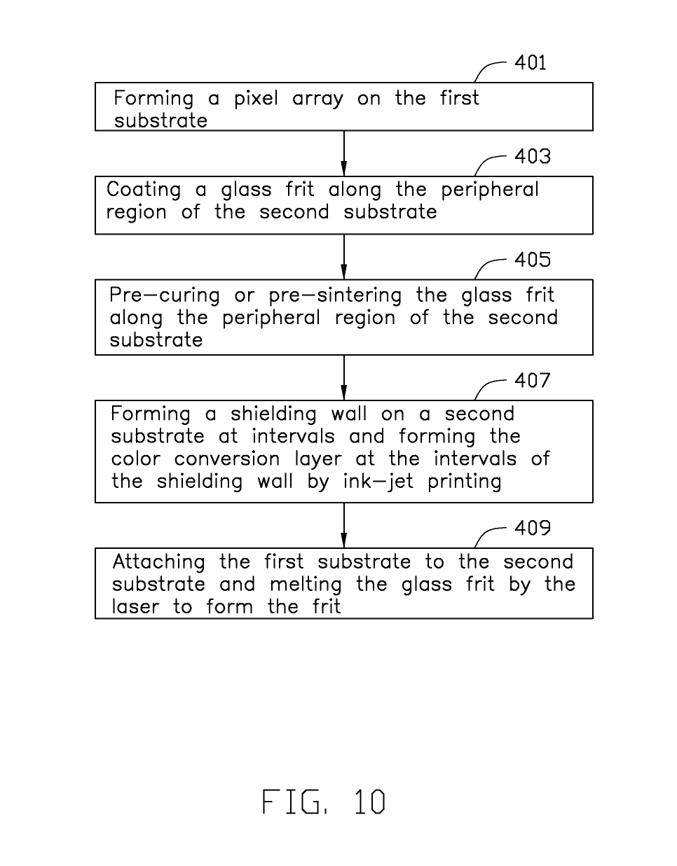

FIGS. 7-9 are sectional views illustrating a manufacturing method of the organic light emitting display device 20. FIG. 10 is a flowchart of the manufacturing method of the organic light emitting display device 20. The method is provided by way of example, as there are a variety of ways to carry out the method. Each block shown in FIG. 10 represents one or more processes, methods, or subroutines which are carried out in the example method. Furthermore, the order of blocks is illustrative only and the order of the blocks can change. Additional blocks can be added or fewer blocks may be utilized without departing from the scope of this disclosure. The example method can begin at block 201.

At block 401, FIG. 7 illustrates the pixel array 230 is formed on the first substrate 210. In the embodiment, the pixel array 230 emits monochromatic light.

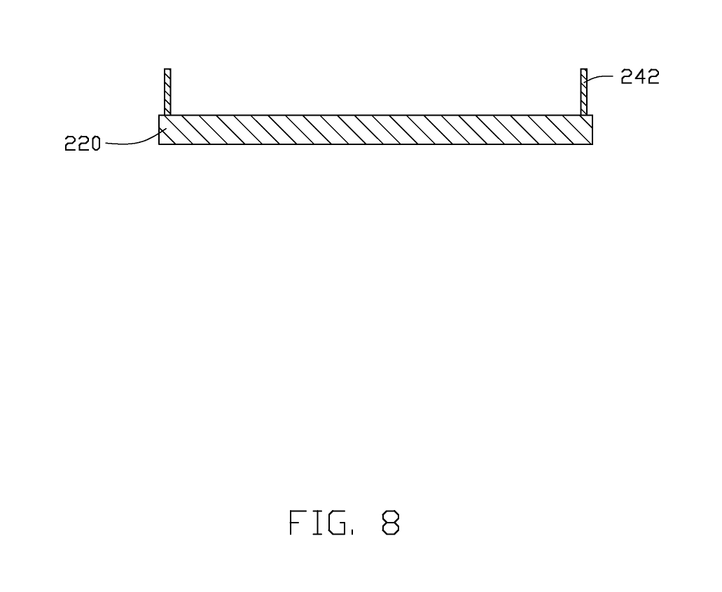

At block 403, FIG. 8 illustrates a shielding wall 224 is formed on a second substrate 220 at intervals and the color conversion layer 226 is formed at the intervals of the shielding wall 224 by ink-jet printing. In the embodiment, the filler material 2260 and quantum 260 are mixed and then deposited in intervals on the shielding wall 224 to form the color conversion layer 226 by ink-jet printing. In one embodiment, the shielding wall 224 can be formed by screen printing technology.

At block 405, FIG. 9 illustrates the glass frit 242 is deposited along the peripheral region of the second substrate 220. The glass frit 242 can be deposited on the second substrate 220 one millimeter away from the edges of the second substrate 220. In the embodiment, the glass frit 242 is coated along the edges of the second substrate 220 by dispenser or screen printing.

At block 407, FIG. 9 illustrates the glass frit 242 is pre-cured or pre-sintered along the edges of the second substrate 220 to surround the shielding wall 224.

At block 409, FIG. 6 illustrates the first substrate 210 is attached to the second substrate 220; the glass frit 242 is melted by the laser to form the frit sealant 240. In other embodiments, the glass frit 242 can be melted by infrared.

The organic light emitting display device 20 includes the frit sealant 240. The frit sealant 240 is made of inorganic material, thus the frit sealant 240 can block outside moisture or oxygen and the epoxy is omitted. Further, when the organic light emitting display device is sealed by laser, the second substrate with the color conversion layer serves as a packaging substrate and the color conversion layer also serves as a buffer material to ensure mechanical strength of the laser melting seal and make packaging more reliable.

It is to be understood that even though numerous characteristics and advantages of the present embodiments have been set forth in the foregoing description, with details of the structures and functions of the embodiments, the disclosure is illustrative only; and changes may be in detail, especially in the matter of arrangement of parts within the principles of the embodiments to the full extent indicated by the broad general meaning of the terms in which the appended claims are expressed.

What is claimed is:

1. An organic light emitting display device, comprising:
a first substrate;
a second substrate located opposite to the first substrate;
a pixel array arranged between the first substrate and the second substrate to emit monochromatic light;
a fit sealant arranged between the first substrate and the second substrate to surround the pixel array; and
a color conversion layer doped with quantum dots and arranged on the second substrate.

2. The organic light emitting display device of claim 1, wherein the color conversion layer comprises a shielding wall and a color conversion unit; and the color conversion unit is doped with a filler material and the quantum dots.

3. The organic light emitting display device of claim 2, wherein the shielding wall is formed on the second substrate with intervals, the color conversion unit comprises a first color conversion unit, a second color conversion unit, and a third color conversion unit, and the first, second, and third color conversion unit are deposited at the intervals of the shielding wall.

4. The organic light emitting display device of claim 2, wherein the filler material is epoxy, acrylic plastic or other transparent material.

5. The organic light emitting display device of claim 1, wherein the frit sealant is made of glass frit deposited on edges of the second substrate by pre-curing or pre-sintering; and
when the first substrate is attached to the second substrate, the glass frit is heated by laser beam to melt the glass frit.

6. The organic light emitting display device of claim 5, wherein the frit sealant is formed by melting the glass frit to seal the first substrate and the second substrate.

7. The organic light emitting display device of claim 5, wherein the glass frit comprises at least one kind of absorption ion.

8. The organic light emitting display device of claim 7, wherein a height of the frit sealant is adjusted to control a space between the color conversion layer and the pixel array.

9. The organic light emitting display device of claim 8, wherein the absorption is iron ion, copper ion, barium ion or neodymium ion.

10. The organic light emitting display device of claim 8, wherein there is no space between the color conversion layer and the pixel array.

11. A manufacturing method of an organic light emitting display device, comprising:
forming a pixel array on a first substrate to emit monochromatic light;
forming a color conversion doped with quantum dots on a second substrate opposite to the first substrate;
coating a glass frit on the second substrate to surround the color conversion layer; and
attaching the first substrate to the second substrate and forming a frit sealant to seal the first substrate and the second substrate by melting the glass frit.

12. The manufacturing method of claim 11, wherein the glass frit is coated along the edges of the second substrate by dispenser or screen printing.

13. The manufacturing method of claim 11, wherein the color conversion layer comprises a shielding wall and a color conversion unit, the shielding wall is formed on the second substrate with intervals and the color conversion layer is formed at the intervals of the shielding wall by ink-jetting printing.

14. The manufacturing method of claim 11, wherein the color conversion layer comprises a shielding wall and a color conversion unit, the shielding wall is formed on the second substrate with intervals, and a filler material and quantum dots are doped into intervals of the intervals of the shielding wall by micro-contact printing to form the color conversion unit.

15. The manufacturing method of claim 11, wherein the color conversion layer comprises a shielding wall and a color conversion unit; and the color conversion unit is doped with a filler material and the quantum dot.

16. The manufacturing method of claim 15, wherein the shielding wall is formed on the second substrate with intervals, the color conversion unit comprises a first color conversion unit, a second color conversion unit, and a third color conversion unit, and the first, second, and third color conversion unit are deposited at the intervals of the shielding wall.

17. The manufacturing method of claim 16, wherein the filler material is epoxy, acrylic plastic or other transparent material.

18. The manufacturing method of claim 17, wherein the frit sealant is made of glass fit deposited on edges of the second substrate by pre-curing or pre-sintering; and when the first substrate is attached to the second substrate, the glass fit is heated by laser to melt the glass fit.

19. The manufacturing method of claim 11, wherein a height of the fit sealant is adjusted to control a space between the color conversion layer and the pixel array.

20. An organic light emitting display device, comprising:
a first substrate;
a second substrate located opposite to the first substrate;
a pixel array arranged between the first substrate and the second substrate and configured to emit monochromatic light;
a frit sealant arranged between the first substrate and the second substrate surrounding the pixel array, the frit sealant being oxygen and moisture impermeable; and
a color conversion layer doped with quantum dots and arranged on the second substrate, comprising a plurality of sets of color conversion units separated by shielding wall.
